(19) United States
(12) Patent Application Publication
(10) Pub. No.: US 2016/0027518 A1
(43) Pub. Date: Jan. 28, 2016

(54) MEMORY DEVICE AND METHOD FOR CONTROLLING THE SAME

(71) Applicant: KABUSHIKI KAISHA TOSHIBA, Tokyo (JP)

(72) Inventor: Tatsuya ZETTSU, Yokohama Kanagawa (JP)

(21) Appl. No.: 14/634,708

(22) Filed: Feb. 27, 2015

(30) Foreign Application Priority Data
Jul. 22, 2014 (JP) 2014-149076

(51) Int. Cl. G11C 16/14

(52) U.S. Cl. CPC G11C 16/14

(57) ABSTRACT

A memory device connectable to a host device includes a non-volatile semiconductor memory unit including a plurality of memory blocks, each of the memory blocks including a plurality of pages, and a control unit configured to carry out data writing in the non-volatile semiconductor memory unit in units of a page and data erasing in the non-volatile semiconductor memory unit. When the control unit carries out data writing of a plurality of pages, the control unit splits data erasing of one memory block into a plurality of sub erasing steps and carries out one sub erasing step between the data writing of pages.

### CROSS-REFERENCE TO RELATED APPLICATION

This application is based upon and claims the benefit of priority from Japanese Patent Application No. 2014-149076, filed Jul. 22, 2014, the entire contents of which are incorporated herein by reference.

### FIELD

Exemplary embodiments described herein relate to a memory device and a method for controlling the same.

### BACKGROUND

Data stored in a NAND flash memory, which is used in solid state drives (SSD) and other devices, is erased by a block, and is programmed by a page. When data is programmed at a page of a block, the page has to be not programmed after being erased. When a write request is received from a host device and there is no block to program the data, a block have to be erased before being programmed for writing the data. It makes latency of the write request longer because of the erasure.

### DESCRIPTION OF THE DRAWINGS

FIG.1 is a block diagram illustrating a memory device according to a first embodiment.

FIG. 2 illustrates a process of data writing in a NAND memory of the memory device according to the first embodiment.

FIG. 3 is a schematic diagram illustrating a garbage collection carried out in a NAND memory of the memory device according to the first embodiment.

FIG. 4 is a schematic diagram illustrating an order of data writing to the NAND memory of the memory device according to the first embodiment.

FIG. 5 is a schematic diagram illustrating a deadline to complete a block erasing in the NAND memory of the memory device according to the first embodiment.

FIG. 6 is a schematic diagram illustrating split of the block erasing and a timing to determine which block is erased in the NAND memory of the memory device according to the first embodiment.

FIG. 7 is a schematic diagram illustrating a timing of the block erasing in the memory device according to the first embodiment.

FIG. 8 is a schematic diagram illustrating an order of data writing in a NAND memory of a memory device according to a second embodiment.

FIG. 9 is a schematic diagram illustrating an order of data writing in a NAND memory of a memory device according to a third embodiment.

FIG. 10 is a schematic diagram illustrating an order of data writing in a NAND memory of a memory device according to a fourth embodiment.

FIG. 11 is a schematic diagram illustrating timing of data writing and block erasing in a NAND memory of a memory device according to a fifth embodiment.

FIG. 12 is a schematic diagram illustrating an order of data writing and block erasing in a NAND memory of a memory device according to a sixth embodiment.

FIG. 13 is a schematic diagram illustrating timing of data writing and block erasing in the NAND memory of the memory device according to the sixth embodiment.

FIG. 14 is a flowchart of a method for determining a block erasing destination carried out by a memory device according to a seventh embodiment.

### DETAILED DESCRIPTION

One or more of the embodiments provide a memory device that stabilizes latency of write requests from a host device.

According to an embodiment, there is provided a memory device connectable to a host device including a non-volatile semiconductor memory unit including a plurality of memory blocks, each of the memory blocks including a plurality of pages, and a control unit configured to carry out data writing in the non-volatile semiconductor memory unit in units of a page and data erasing in the non-volatile semiconductor memory unit. When the control unit carries out data writing of a plurality of pages, the control unit splits data erasing of one memory block into a plurality of sub erasing steps and carries out one sub erasing step between the data writing of pages.

Hereinafter, embodiments will be described with reference to the accompanying drawings.

### First Embodiment

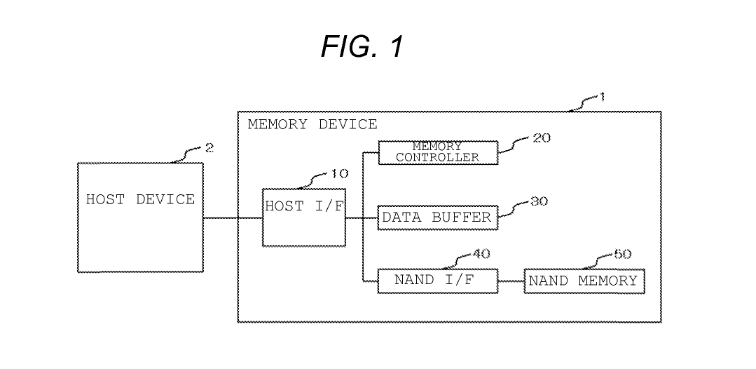

FIG. 1 is a block diagram illustrating a memory device 1 according to a first embodiment. The memory device 1 includes a host interface (I/F) 10, a memory controller 20, a data buffer 30, NAND interface (I/F) 40 and a NAND memory 50. The memory device 1 may be connected to the host device 2, and FIG. 1 illustrates a state where the memory device 1 is connected to the host device 2. For example, the host device 2 is an electronic device such as a personal computer and a portable terminal.

The host I/F 10 is connected to the host device 2 through connection and transfers data between the host device 2 and the memory device 1 under a communication protocol. Example of the connection is a serial bus such as serial advanced technology attachment (SATA), an address bus, a data bus, and the like. The host I/F 10 receives a read/write command from the host device 2, the read/write command includes a logical address (logical block addressing, LBA) and a size of requested data to be read/written (for example, the number of sectors, and one sector has, for example, 512 bytes).

The memory controller 20 controls the entire operation of the memory device 1. The memory controller 20 interprets a command transmitted from the host device 2 through the host I/F 10, and writes data to the NAND memory 50 via the NAND I/F 40 or read out data from the NAND memory 50.

The data buffer 30 is a memory used to temporarily store data received from the host device 2 until the memory controller 20 stores the data in the NAND memory 50, or temporarily store data read from the NAND memory 50 until the memory controller 20 transmits the data to the host device 2. The data buffer 30 is, for example, a general-purpose memory such as a static random access memory (SRAM), and a dynamic random access memory (DRAM).

The NAND I/F 40 controls the NAND memory 50 and includes an error correction circuit.

The NAND memory 50 is a NAND type flash memory and includes a memory cell array formed of a plurality of non-volatile memory elements. It is possible to read and write data in units of a page. It is possible to erase data in units of a block, which is an integer multiple of the page. In the description below, a memory area of the NAND memory 50 in which one page data is stored is referred to as a page. A memory area of the NAND memory 50 in which one block data is stored is referred to as a block. Accordingly, one block consists of a plurality of pages. In one example, a size of one page is 4 KB and 64 pages are contained in one block. The memory cell array includes a plurality of blocks.

Here, the NAND memory is used as the non-volatile semiconductor memory, but in alternative embodiments other memory different from the NAND memory may be used.

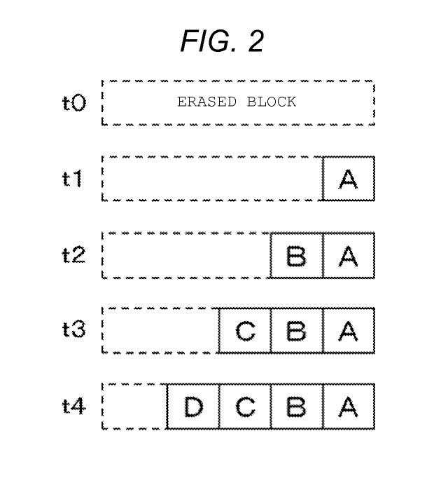

Data writing to the NAND memory 50 will be described using FIG. 2. For example, a writing method, which will be described below, is employed for data writing to the NAND memory 50. It is necessary to secure one or more block, as a data writing destination, before data writing is started. In the NAND memory 50, it is possible to write data to a page that has not been programmed after erased, but it is not possible to write data again to a page has already been programmed. An LBA in a write command received from the host device 2 is converted into a physical address, which is a physical memory location of the NAND memory 50, with respect to each data writing request from the host device 2, and then data is written at the page designated by the physical address.

In particular, as illustrated in FIG. 2, at the time to, a block is erased and the block is held to write other data. At the time t1, first data A is written at the first page of the block, which is the data writing destination (the head or the tail), and at the time t2, data B is written at the second page. Similarly, at the time t3, data C is written at the third page, and at the time t4, data D is written at the fourth page.

The memory controller 20 includes, as a logical-to-physical translation table, a map from an LBA to a physical address indicating a memory location in which each data is written. When a new data writing request is transmitted from the host device and the LBA there in is the same as the LBA designated by a previous data writing request, the memory device 1 writes new data at a page of an erased block where data has not been written. In this case, the memory device 1 makes a page which holds the data of the previous write request invalid, and makes a page which holds the data of the write request valid.

Here, when data is invalid, it means that there is no logical address in association with the data. When data is valid, it means that there is a logical address associated with the data. When a page is invalid, it means that there is no logical address associated with the page. When a page is valid, it means that there is a logical address associated with the page.

As more data are written to the NAND memory 50, available blocks for data writing decrease and invalid pages increase. As a result, capacity of the NAND memory 50 available for data writing decreases. Accordingly, the memory device 1 performs a garbage collection at an appropriate timing, so that a block available for data writing is secured.

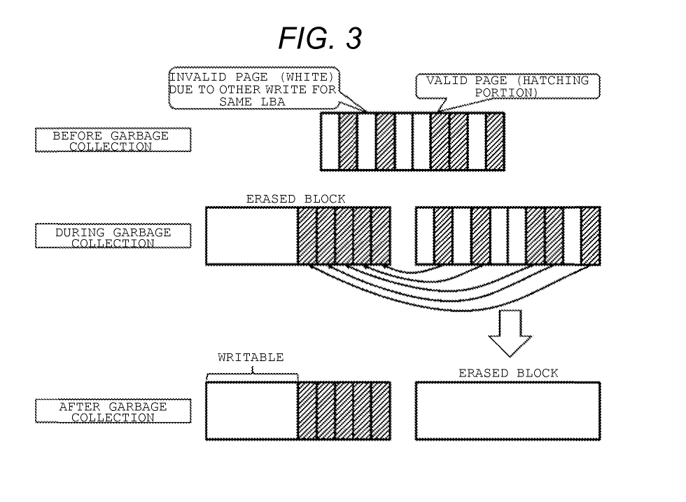

FIG. 3 is a schematic diagram illustrating the garbage collection. As illustrated in FIG. 3, a block (garbage collection target) contains both valid and invalid data. The memory device 1 collects valid data in pages of the block (garbage collection target data) and writes the collected data in an erased block, i.e., transfers the garbage collection target data to the erased block. Then, the memory device 1 erases data from the block where the transferred garbage collection target data has been stored, and thus a block available for data writing is secured. If there is a blank page where data is not written in the block where the garbage collection target data has been written resulting from the data transfer, it is possible to write new data in the blank page.

At least one erased block is required in order to perform this garbage collection, which means that data volume available for data writing from the host device 2 (declared capacity) is smaller than a physical capacity of the NAND memory 50 (actual capacity).

In the memory device 1, a ratio of data volume of data requested to be written from the host device 2 (writing-requested data) with respect to data volume of the garbage collection target data is within a predetermined range. For simple description, this ratio is set to a constant value C(GC(Garbage Collection)/H (Host)) (C(GC/H)) and the embodiments will be described below.

When the writing-requested data and the garbage collection target data are written to the NAND memory 50, it is necessary to also write a predetermined volume of logical-to-physical translation table data. This ratio, that is, a value which is obtained by dividing a sum of data volume of the writing-requested data and the garbage collection target data (user data) by data volume of the logical-to-physical translation table data to be written to the NAND memory 50, is within a predetermined range. For simple description, the minimum value of this ratio is set to C(UD(User Data)/T(Translation Table Data)) (C(UD/T)), and the embodiments will be described below.

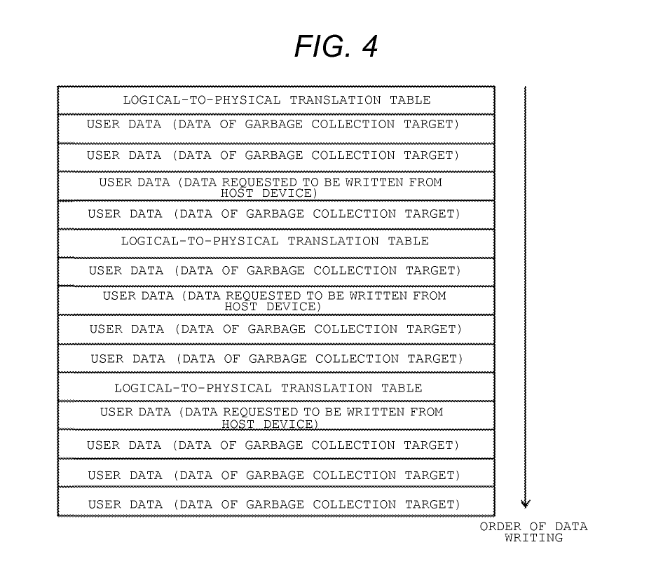

FIG. 4 is a schematic diagram illustrating an order of data writing to the NAND memory 50 when C(GC/H) is 3 and C(UD/T) is 4 and under conditions where writing-requested data and the garbage collection target data are written to the NAND memory 50.

The memory device 1 splits data erasing operation of one block of the NAND memory 50 (referred to below simply as “block erasing”) into a plurality of data erasing operations and performs the spit data erasing operations (referred to below simply as “split erasing”) accordingly. That is, split erasing is performed each time a predetermined volume of user data is written to the NAND memory 50.

Each time writing-requested data of one block is written, garbage collection target data of C(GC/H) block is written. In this case, it is necessary to erase data from (1+C(GC/H)) blocks of the NAND memory 50 per one block of the writing-requested data, in order to secure sufficient number of blocks for the writing-requested data and the garbage collection target data.

C(GC/H) is a parameter that is configurable by the firmware and may be determined based on, for example, the declared capacity or the actual capacity. When data stored in a block of the NAND memory 50 is transferred and then data in the block is erased during a previous garbage collection, respective quantity of valid pages and invalid pages in a block to be erased may be measured, and then C(GC/H) may be determined based on the practical measurement result. The LBA of writing-requested data may be stored, and then C(GC/H) may be determined based on an access pattern indicating that these LBAs are continuous or sparse. The more continuous LBAs become, the higher probability becomes that a block may be detected where data movement is completed in small amount during garbage collection, and the smaller C(GC/H) may become.

One block of the NAND memory 50 corresponds to C(P (Page)/B(Block)) pages in size. In other words, one block consists of C(P (Page)/B(Block)) pages. C(P (Page)/B(Block)) is a constant determined by characteristics of the NAND memory 50. Data writing unit in the NAND memory 50 is one page, and accordingly, data of one page is written during one data writing process. Thus, it is necessary to perform data erasing of one block each time writing-requested data of (C(P/B)/(1+C(GC/H)) pages is written by in the NAND memory 50. In other words, it is necessary to perform data erasing of one block per (C(P/B)/(1+C(GC/H)) times of data writing of the writing-requested data. For convenience of explanation, (C(P/B)/(1+C(GC/H)) is referred to as C(Span) below.

A deadline to complete erasing of one block (erasing completion deadline) is a timing when data of a last page, among C(Span) pages, is written to the NAND memory 50.

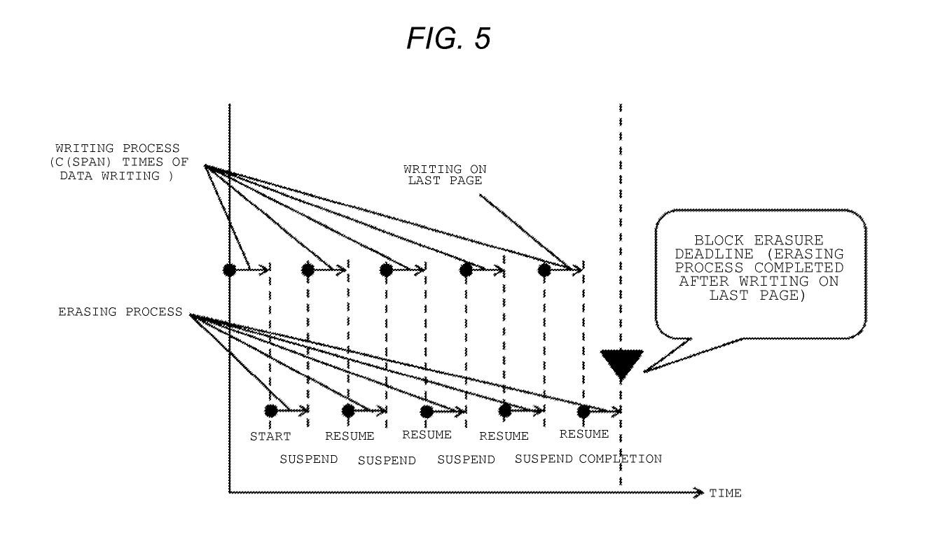

FIG. 5 is a schematic diagram illustrating a deadline at which data erasing of one block in the NAND memory 50 is completed in the memory device 1 when C(Span) is 5. FIG. 5 shows that erasing of one block is completed when the last page among C(Span) pages is written to the NAND memory 50.

When block erasing of the NAND memory 50 is performed through the split erasing, there is a minimum time required for each of the split erasing process. Accordingly, when block erasing is performed for one block, an available splitting number has an upper limit. The upper limit is an integer determined by characteristics of the NAND memory 50, and the like. For convenience of description, the upper limit is referred to as C(MaxSplit) hereinafter. Thus, the number of split erasing of erasing in one block should be a smaller one of C(MaxSplit) and C(Span).

When data writing request on data of C(Span) pages is received from the host device 2, a time period necessary for writing to the NAND memory 50 is the sum of a time period for writing the writing-requested data to the NAND memory 50, a time period for writing the garbage collection target data to the NAND memory 50, and a time period for erasing one block of the NAND memory 50. A value obtained by dividing this value by a smaller value of C(MaxSplit) and C(Span), which is equal to a total time period necessary for writing one page of the writing-requested data to the NAND memory 50, is the maximum latency of a write request from the host device 2 to the memory device 1.

A block to be erased is determined by the time the data erasing starts. That is, a block to be erased is determined at a timing early enough so that data writing on a number of pages equal to a smaller value of C(MaxSplit) and C(Span) can be completed prior to the erasing completion deadline.

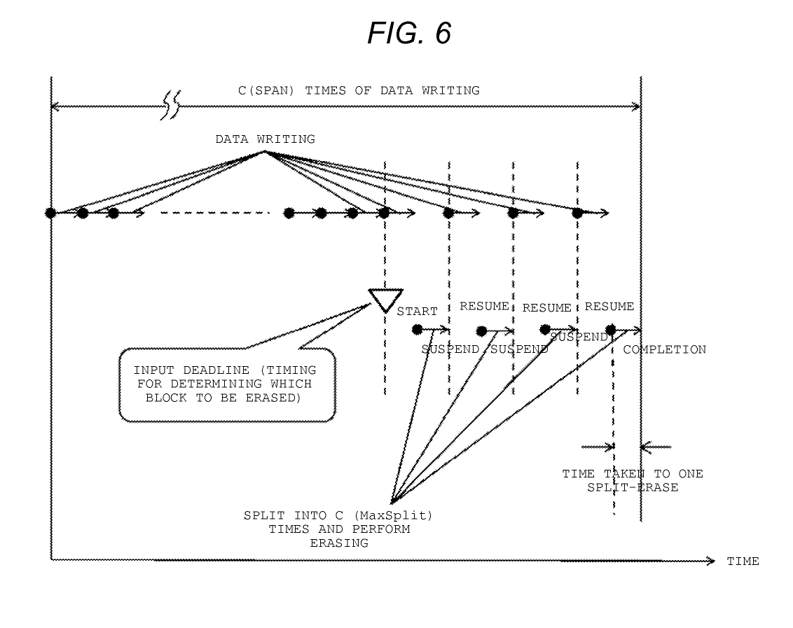

FIG. 6 is a schematic diagram illustrating a timing at which an erasing target block is determined. FIG. 6 illustrates an example of when C(MaxSplit) is 4, C(MaxSplit) is less than C(Span), and block erasing is split into C(MaxSplit). As illustrated in FIG. 6, one-block data is erased from the NAND memory 50 while the writing-required data and the garbage collection target data are written in the NAND memory 50 C(MaxSplit) times.

There maybe situations where a data writing request from the host device 2 is not received at all, such as when all the data in the NAND memory 50 are requested to be erased. In this case, in order to increase a response speed with respect to an erasing request from the host device 2, when the request of erasing only is continuously received from the host device 2 predetermined times, erasing of the NAND memory 50 is not split but performed collectively. In another example, when a battery is built in the memory device 1 and the power supply is cut off while the memory device 1 is operated, whether or not it is possible to continue a process after the termination of the power supply is determined based on a battery capacity when the power supply is cut off. Then, how to perform erasing after the termination is determined according to the determination result. When it is determined that battery capacity is not enough to continue the erasing, erasing is not restarted. When it is determined that battery capacity is enough to continue the data erasing, the data erasing is not split, but continuously performed to complete the data erasing.

When a write request is not received from the host device 2, it seems that it is not necessary to perform data writing to the NAND memory 50. However, if data is not written at a page in an erased block for a predetermined time after data has been erased from the block, an error is likely to occur when data is written and then read at the pages of the block not yet written to. To avoid this issue, when a write request is not received from the host device 2 for a predetermined time period, dummy data is written to the NAND memory 50, and data writing is completed at the all pages of the block within the predetermined time. In this manner, the dummy data writing is scheduled as if a write request was received from the host device 2, and a timing of erasing new writing destination is determined.

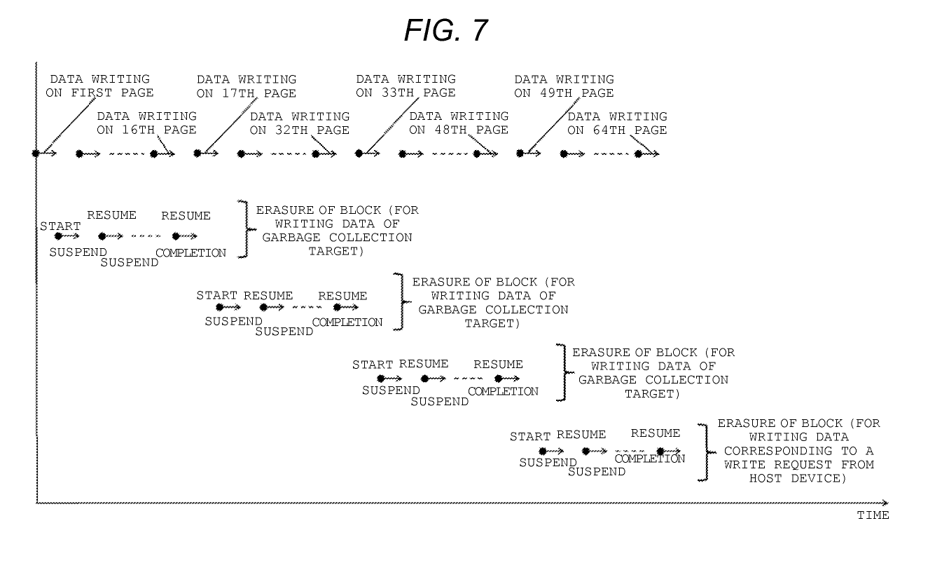

FIG. 7 is a schematic diagram illustrating a timing at which block erasing is performed when C(GC/H) is 3, C(P/B) is 64, C(MaxSplit) is 16, C(Span) is 16, a time period necessary for erasing one block of the NAND memory 50 is 30 msec, and a time period necessary for writing data at one page of the NAND memory 50 is 10 msec to the NAND memory 50 in the memory device 1 according to the first embodiment.

In FIG. 7, block erasing of four blocks is performed, and three blocks of the four blocks are used for writing garbage collection target data, and one block of the four blocks is used for writing the writing requested data. While data is written from the first page to the 48th page, three blocks are erased for the garbage collection target data. While data is written from the 49th page to the 64th page, data of one block is erased for the writing requested data from the host device 2.

Since C(Span) is 16, one block is erased each time data of 16 pages is written to the NAND memory 50. Since C(MaxSplit) is 16, it is possible to split the data erasing of one block into 16 steps. Accordingly, it is possible to perform the split erasing, each time data of one page is written to the NAND memory 50. A target block on which the split erasing is performed is determined before data is written at the first page, the 17th page, the 33th page, and the 49th page.

For example, when 10 msec is used for one split erasing each time the data writing is performed on the writing-requested data from the host device 2, the maximum latency of a write request from the host device 2 is 20 msec, which is a summation of a time taken to perform data writing of the writing-requested data from the host device 2 and a time used to perform one split erasing. Accordingly, it is possible to guarantee that the maximum latency of a write request from the host device 2 is 20 msec.

When the maximum latency of a write request from the host device 2 is designated, the memory controller 20 determines time of one split erasing to meet the maximum latency. For example, when the maximum latency of a write request from the host device 2 is designated as 15 msec, it is necessary that the time used to perform one split erasing is 5 msec. In this case, a summation of processing time taken to erase one block is 80 msec.

Here, for comparison, it is assumed that single block erasing (without split) is performed whenever a blank block for data writing becomes necessary. In this case, the data writing of the writing-requested data from the host device 2 to the NAND memory 50 may have to be carried out after the block erasing of a writing destination block is performed. As the processes have to be performed in the order of the block erasing and then the data writing, the latency is increased by a time taken to perform the block erasing.

On the other hand, according to the first embodiment described above, it is possible to equalize a latency of a write request from the host device 2 to the sum of a time taken for the data writing of the writing-requested data to the NAND memory 50 and a time taken to perform one split erasing from the NAND memory 50. Further, it is possible to guarantee the maximum latency of a write request from the host device 2.

### Second Embodiment

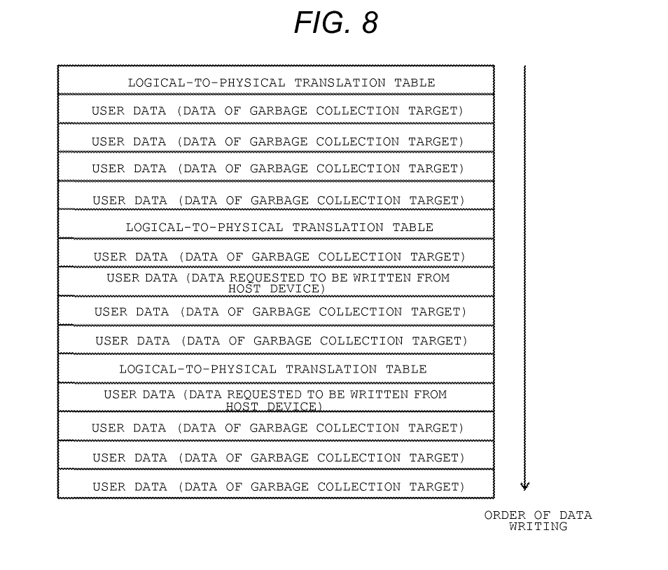

FIG. 8 is a schematic diagram illustrating an order of data writing in a NAND memory 50 when C(GC/H) is 2 in a memory device according to a second embodiment. A configuration of the memory device according to the second embodiment is the same as the configuration of the memory device 1 according to the first embodiment illustrated in FIG. 1.

This second embodiment is different from the first embodiment in that when a write request from the host device 2 is not received, the garbage collection target data is written, instead of the dummy data. In this case, it is possible to proceed with the garbage collection and to decrease C(GC/H) in the long term.

Alternatively, when a write request from the host device 2 is not received, no data maybe written and new block erasing may not be performed. Even when there is a timing when the data writing of the writing-requested data can be performed, a write request from the host device 2 may not be received. In such as case, an erased block may be already prepared for when a next write request from the host device 2, and it is not necessary to perform new block erasing. That is, block erasing may be skipped as with writing of dummy data to the NAND memory 50.

According to the second embodiment described above, as in the first embodiment, it is possible to guarantee the maximum latency of a write request from the host device 2. Further, it is possible to proceed with the garbage collection and to decrease C(GC/H) in the long term.

### Third Embodiment

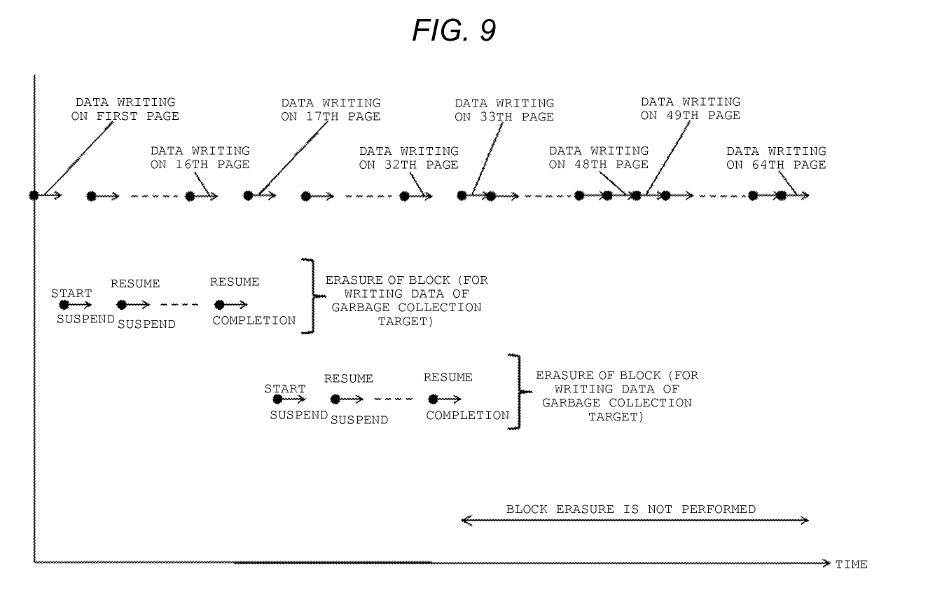

FIG. 9 is a schematic diagram illustrating an order of data writing in a NAND memory 50 in a memory device according to a third embodiment. A configuration of the memory device according to the third embodiment is the same as the configuration of the memory device 1 according to the first embodiment illustrated in FIG. 1.

This third embodiment is different from the first embodiment in that, when a block to be erased is not present at a timing even though the block erasing can be performed in the NAND memory 50, data writing of the garbage collection is continued instead of the block erasing (as illustrated with data writing on 33th page through 64th page), because there is already sufficient amount of erased blocks, which is equal to or more than a predetermined value, or the like. In this case, it is possible to proceed with the garbage collection and to decrease C(GC/H) in the long term.

According to the third embodiment described above, as in the first embodiment, it is possible to guarantee the maximum latency of a write request from the host device 2. As in the second embodiment, it is possible to proceed with the garbage collection and to decrease C(GC/H) in the long term.

### Fourth Embodiment

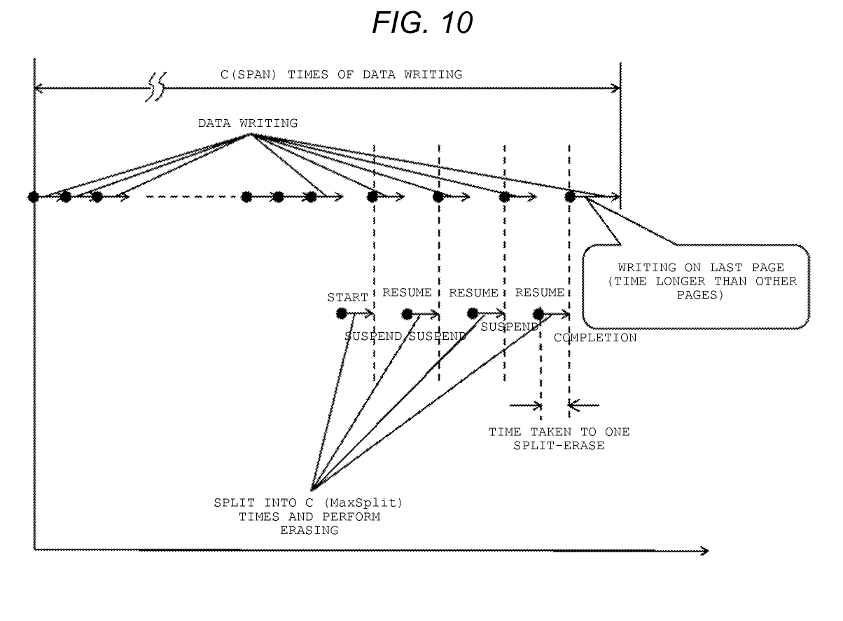

FIG. 10 is a schematic diagram illustrating an order of data writing to the NAND memory 50 in a memory device according to a fourth embodiment. A configuration of the memory device according to the fourth embodiment is the same as the configuration of the memory device 1 according to the first embodiment illustrated in FIG. 1.

The fourth embodiment is different from the first embodiment in that execution timing of the block erasing is changed in case time to write a page depends on its page number in the NAND memory 50.

The NAND memory 50 may be a SLC(Single Level Cell) type NAND memory in which one bit is stored in one memory cell, and may be a MLC(Multi Level Cell) type NAND memory in which two or more bits are stored in one memory cell. When the NAND memory 50 is a MLC type NAND memory, data of two pages may be stored in each memory cell of the NAND memory 50. A page where writing has been previously performed is a lower page, and a page where writing is performed subsequent to the lower page is an upper page. In a MLC type NAND memory, in order to reduce a program disturbance due to coupling capacitance between adjacent memory cells, the order of writing at the lower page and the upper page is determined. The data writing is repeatedly performed plural times, which includes a writing operation of writing data at a memory cell and a verifying operation of verifying data written in the memory cell. However, the data writing is performed to write data to cells more precisely for the last writing, and takes longer time. As the last writing, which takes time, is performed for the last page of a block, time to write data to the last page becomes longer than time to write data to other pages. Thus, time to write data to a page depends on its page number in the NAND memory 50.

According to the fourth embodiment, when a page on which the writing-requested data from the host device 2 is to be written is a page that requires a long writing time, split erasing is not performed. In contrast, when the page is a page that needs only a short writing time, split erasing is performed.

In an example shown in FIG. 10, the last page of pages, which are data writing destinations, is the page that requires a long writing time, and split erasing is not performed when data writing on the last page is performed.

According to the fourth embodiment, it is possible to stabilize a latency or a write request from the host device 2, and to guarantee the maximum latency of a write request from the host device 2. When the garbage collection target data is written, if there is a difference of writing times depending on a page of a data writing destination, whether or not to perform the block erasing is determined based on total writing time obtained including time period to write the writing-requested data from the host device 2. Further, when the data writing on a first page takes a long period of time, the block erasing may not be performed as with the last page.

### Fifth Embodiment

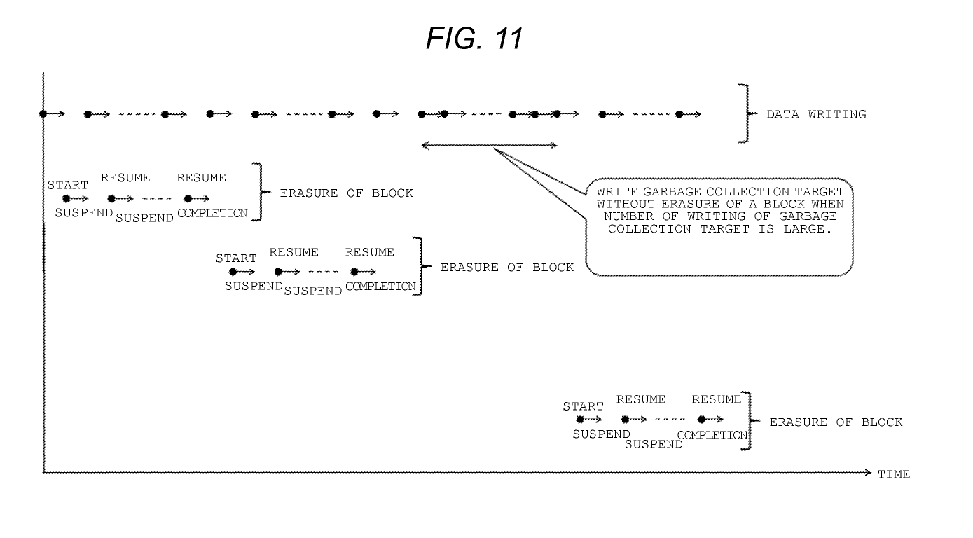

FIG. 11 is a schematic diagram illustrating timing of the data writing and the block erasing from a NAND memory 50 in a memory device according to a fifth embodiment. A configuration of the memory device according to the fifth embodiment is the same as the configuration of the memory device 1 according to the first embodiment illustrated in FIG. 1.

The fifth embodiment is different from the first embodiment in that when the number of pages of garbage collection target data to be written to the NAND memory 50 is different, execution timing of the block erasing is changed.

When C(GC/H) is not an integer, the number of writing pages of garbage collection target data is different depending on a timing at which a write request is received from the host device 2. In this case, the block erasing is performed when the number of writing pages of the garbage collection target data is small, and the block erasing is not performed when the number of writing pages of the garbage collection target data is large. With this operation, it is possible to stabilize a latency of a write request from the host device 2.

According to the fifth embodiment described above, as in the first embodiment, it is possible to guarantee the maximum latency of a write request from the host device 2.

### Sixth Embodiment

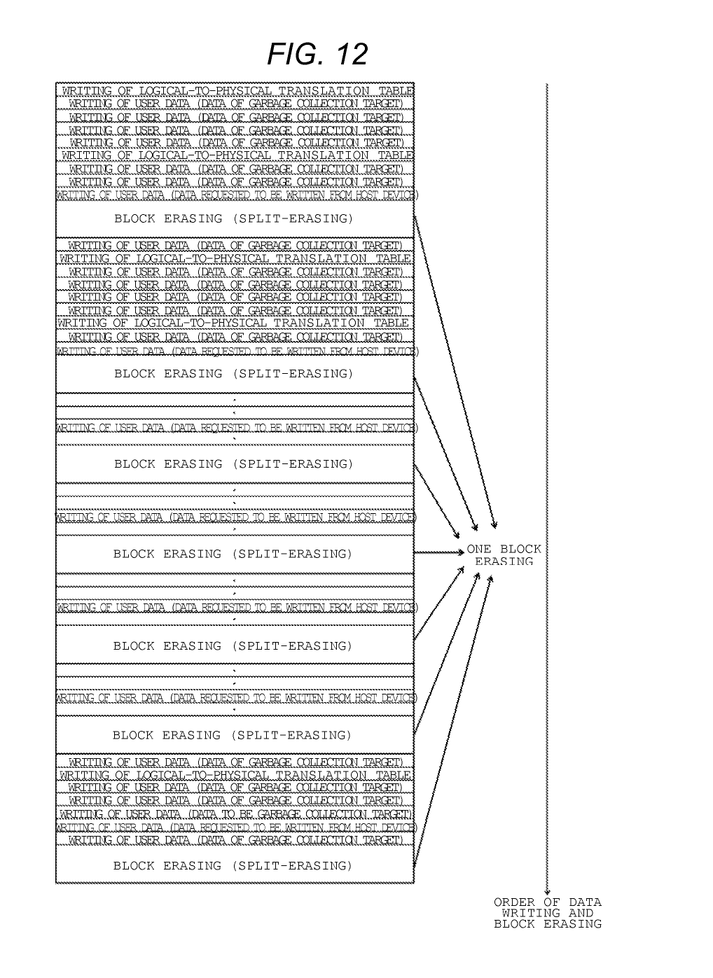

FIG. 12 is a schematic diagram illustrating an order of the data writing and the block erasing in the NAND memory 50 when C(GC/H) is 6, C(UD/T) is 4, C(MaxSplit) is 7, C(Span) is 7 in the memory device 1 according to a sixth embodiment. A configuration of the memory device according to the sixth embodiment is the same as the configuration of the memory device 1 according to the first embodiment illustrated in FIG. 1.

In the sixth embodiment, the split erasing is performed so as to erase data of one block each time data of seven pages is written to the NAND memory 50 according to a write request from the host device 2.

The number of pages of the NAND memory 50, on which the logical-to-physical translation table is written, is ((1+C(GC/H))/C(UD/T) with respect to writing of one-page data requested to be written from the host device 2. As ((1+C(GC/H))/C(UD/T) includes division, the number of pages of the NAND memory 50, on which user data is written in accordance with a write request from the host device 2, is not necessary an integer multiple of the number of the pages on which data of the logical-to-physical translation table is written. Accordingly, when user data is written to the NAND memory 50, in accordance with a write request from the host device 2, the number of pages of the NAND memory 50, on which the logical-to-physical translation table is written, is different depending on the timing of writing the user data to the NAND memory 50 in accordance with a write request from the host device 2.

In the sixth embodiment, when number of pages on which the logical-to-physical translation table is written, is small, the block erasing is performed, and when the number of pages of the NAND memory 50, on which the logical-to-physical translation table is written, is large, the block erasing is not performed.

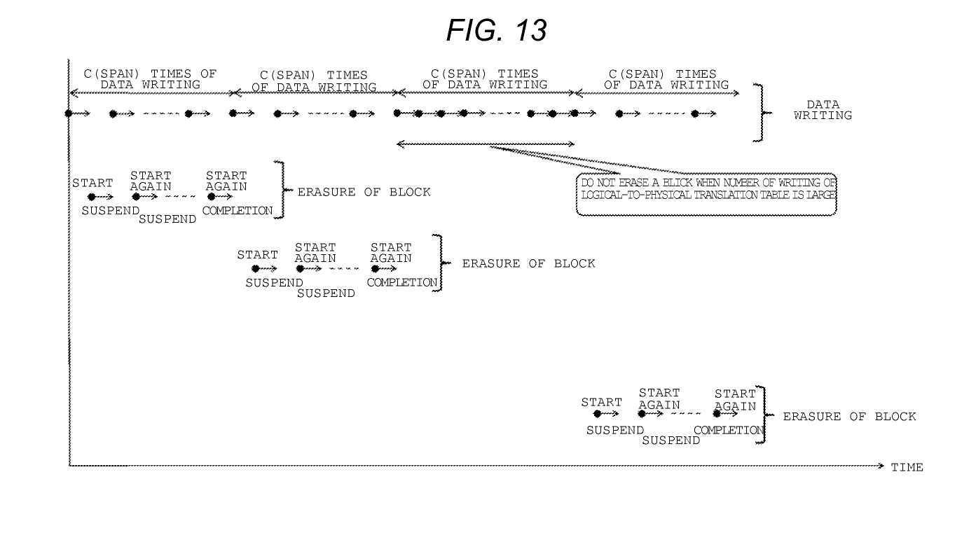

FIG. 13 is a schematic diagram illustrating timing of the data writing and the block erasing from the NAND memory 50 in the memory device according to the sixth embodiment. In an example shown in FIG. 13, the block erasing is not performed because pages of the NAND memory 50, on which the logical-to-physical translation table is written, is large when a write request of data of C(Span) pages is received from the host device 2 after the block erasing has been performed on two blocks.

With this operation, it is possible to stabilize a latency of a write request from the host device 2. Determining whether or not to perform block erasing maybe performed based on total writing time obtained by adding writing time of user data in the NAND memory 50 and writing time of the logical-to-physical translation table in the NAND memory 50.

According to the sixth embodiment described above, as in the first embodiment, it is possible to guarantee the maximum latency of a write request from the host device 2.

### Seventh Embodiment

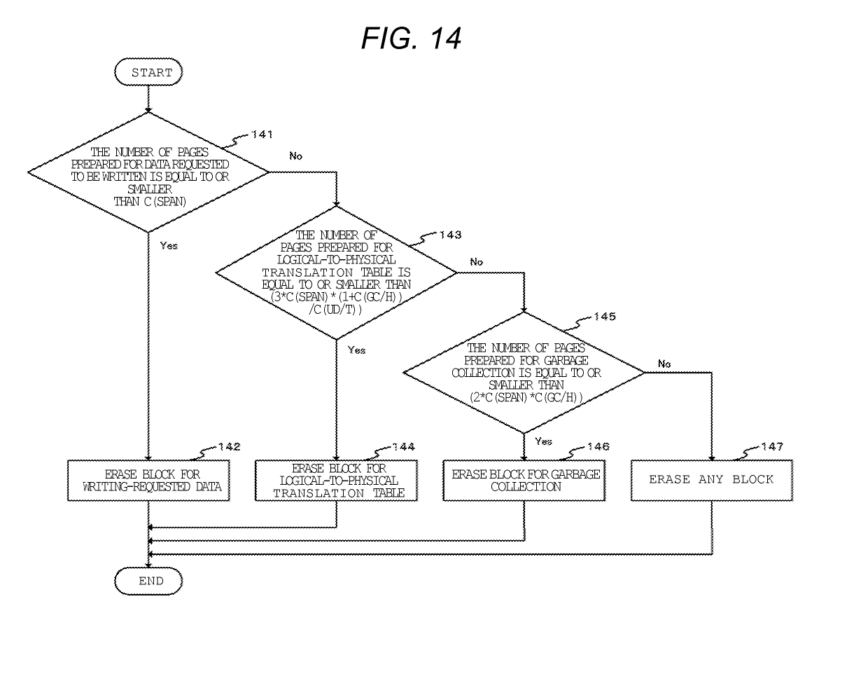

FIG. 14 is a flowchart to determine a block erasing destination in the memory device 1 according to a seventh embodiment. A configuration of the memory device according to the seventh embodiment is the same as the configuration of the memory device 1 according to the first embodiment illustrated in FIG. 1.

This seventh embodiment is different from the first embodiment in that a block erasing destination is selected based on the number of pages for which the data writing has not been performed among pages included in a writing destination block of data.

The maximum latency of a write request from the host device 2 is reduced when block erasing is performed in order to secure separately a writing destination block of data requested to be written from the host device 2, and a writing destination block of garbage collection target data. Accordingly, it is preferable that block erasing timings of these writing destination blocks is not overlapped.

In the seventh embodiment, an erasing target block is determined among a block that is a writing destination of the data requested to be written from the host device 2, a block that is a write destination of the garbage collection target data, and a block that is a write destination of the logical-to-physical translation table, based on capacity of available area for data writing to the NAND memory 50. The maximum latency of a write request from the host device 2 is reduced when the block erasing is performed in order to secure a writing destination of data requested to be written from the host device 2, a write destination of the garbage collection target data, and a write destination of the logical-to-physical translation table. Accordingly, block erasing timings of these writing destination blocks is not likely to be overlapped.

Since it is necessary to perform the block erasing of one block when a write request of C(Span) pages is received from the host device 2, if the number of pages prepared as a writing destination of data requested to be written from the host device 2 is equal to or less than C(Span) (Yes in Step 141), the block is erased prior to write the destination block for the data requested to write from the host device 2 (Step 142).

When the block erasing is performed on the three blocks of a writing block for the data requested to be written from the host device 2, a writing block for the garbage collection target data, and a writing block for the logical-to-physical translation table, if the number of pages secured for the logical-to-physical translation table is smaller than the number of pages needed to write the logical-to-physical translation table generated by data writing to the NAND memory 50, the block erasing is performed on the writing block for the logical-to-physical translation table prior to the writing block for the garbage collection target data. If the number of pages secured for the logical-to-physical translation table is greater than the number of pages needed to write the logical-to-physical translation table generated by data writing to the NAND memory 50, the block erasing is performed on the writing block for the garbage collection target data prior to the writing block for the logical-to-physical translation table. That is, when the block erasing is performed on the three blocks for the writing-requested data from the host device 2, the garbage collection target data, and the logical-to-physical translation table, if the number of pages secured for the logical-to-physical translation table is less than (3*C(Span)*(1+C(GC/H))/C(UD/T)), which is the number of pages for the logical-to-physical translation table generated by the data writing to the NAND memory 50 (Yes in Step 143), the block erasing is preferentially performed on the writing block for the logical-to-physical translation table (Step 144).

In order not to overlap a block erasing timing of a writing block for the garbage collection target data with a block erasing timing of a writing block for the writing-requested data from the host device 2, when the number of pages prepared as a writing for the garbage collection data is smaller than the number of writing pages for the garbage collection target data, which is (2*C(Span)*C(GC/H)) (Yes in Step 145), which are occurred while the block erasing is performed on two blocks of the writing block for the writing-requested data from the host device 2 and the writing block for the garbage collection target data block erasing is preferentially performed on the writing block for the garbage collection target data (Step 146).

When the number of pages prepared as a data writing destination is enough (No in Step 141, No in Step 143, and No in Step 145), the block erasing is randomly performed (Step 147).

According to the seventh embodiment, as in the first embodiment, it is possible to guarantee the maximum latency of a write request from the host device 2. It is possible to avoid a situation where erased block is not present when writing of the data requested to be written from the host device 2, writing of the garbage collection target data, and writing of the logical-to-physical translation table are performed.

The embodiments is not limited thereto, various changes maybe added in a range not departing from a gist of the present disclosure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a non-volatile semiconductor memory unit including a plurality of memory blocks, each of the memory blocks including a plurality of pages; and
a control unit configured to carry out data writing in the non-volatile semiconductor memory unit in units of a page and data erasing in the non-volatile semiconductor memory unit, wherein
when the control unit carries out data writing of a plurality of pages, the control unit splits data erasing of one memory block into a plurality of sub erasing steps and carries out one sub erasing step between the data writing of pages.

2. The memory device according to claim 1, wherein
when the control unit carries out data writing of the plurality of pages, the control unit carries out each of the sub erasing steps after the data writing of one page.

3. The memory device according to claim 1, wherein
when the control unit carries out the data writing of the plurality of pages, data of at least one page among the plurality of pages includes data transmitted from a host device to be written in the non-volatile semiconductor memory unit.

4. The memory device according to claim 1, wherein
when the control unit carries out the data writing of the plurality of pages, data of at least one page among the plurality of pages includes data transferred from another page.

5. The memory device according to claim 1, wherein
when the control unit carries out data writing of the plurality of pages, the control unit is further configured to continuously carry out the data writing of a part of the plurality of pages without carrying out the data erasing therebetween.

6. The memory device according to claim 5, wherein
the control unit continuously carries out the data writing of the part of the plurality of pages without carrying out the data erasing, when a predetermined number of blocks are erased blocks.

7. The memory device according to claim 5, wherein
the data of the plurality of pages includes first data of one or more pages that is transmitted from a host device and second data of one or more pages that is transferred from another page, and
the control unit continuously carries out the data writing of the part of the plurality of pages without carrying out the data erasing, when a ratio of a page number of the second data with respect to a page number of the first data is greater than a predetermined value.

8. The memory device according to claim 5, wherein
the data of the plurality of pages includes first data of one or more pages that is transmitted from a host device and second data of one or more pages that indicates a correlation between a logical address a physical address, and
the control unit continuously carries out the data writing of the part of the plurality of pages without carrying out the data erasing, when a ratio of a page number of the second data with respect to a page number of the first data is greater than a predetermined value.

9. The memory device according to claim 1, wherein
when the control unit carries out the data writing of a plurality of pages, the control unit is further configured to not carry out the sub erasing step after the data writing of one of the pages, if a time period taken for the data writing of the said page is longer than a time period taken for data writing of the other pages.

10. The memory device according to claim 9, wherein
said one of the pages is a last page of the plurality of pages.

11. A method for controlling a memory device having a non-volatile semiconductor memory unit including a plurality of memory blocks, each of the memory blocks including a plurality of pages, the method comprising:
carrying out data writing of a plurality of pages in the non-volatile semiconductor memory unit in units of a page; and
carrying out data erasing of one block in a plurality of sub erasing steps, wherein one sub erasing step is carried out between the data writing of pages.

12. The method according to claim 11, wherein
each of the sub erasing steps is carried out after the data writing of one of the pages.

13. The method according to claim 11, wherein
data of at least one page among the plurality of pages includes data transmitted from a host device.

14. The method according to claim 11, wherein
data of at least one page among the plurality of pages includes data transferred from another page.

15. The method according to claim 11, wherein
the data writing of a part of the plurality of pages is continuously carried out without carrying out the data erasing therebetween.

16. The method according to claim 15, wherein
the data writing of a part of the plurality of pages is continuously carried out, when a predetermined number of blocks are erased blocks.

17. The method according to claim 15, wherein
the data of the plurality of pages includes first data of one or more pages that is transmitted from a host device and second data of one or more pages that is transferred from another page, and
the data writing of a part of the plurality of pages is continuously carried out, when a ratio of a page number of the second data with respect to a page number of the first data is greater than a predetermined value.

18. The method according to claim 15, wherein
the data of the plurality of pages includes first data of one or more pages that is transmitted from a host device and second data of one or more pages that is transferred from another page, and
the data writing of a part of the plurality of pages is continuously carried out, when a ratio of a page number of the second data with respect to a page number of the first data is greater than a predetermined value.

19. The method according to claim 11, wherein
the sub erasing step is not carried out after the data writing of one of the pages, if a time period taken for the data writing of the said page is longer than a time period taken for data writing of the other pages.

20. The method according to claim 19, wherein
said one of the pages is a last page of the plurality of pages.
